(19) United States
(12) Patent Application Publication
(10) Pub. No.: US 2007/0218697 A1
(43) Pub. Date: Sep. 20, 2007

(54) Method for removing polymer from wafer and method for removing polymer in interconnect process

(76) Inventor: Chung-Chih Chen, Hsinchu City (TW)

Correspondence Address: J. C. Patents, Inc., Suite 250, 4 Venture, Irvine, CA, 92618, US

(21) Appl. No.: 11/377,170

(22) Filed: Mar. 15, 2006

(51) Int. Cl. H01L 21/302; H01L 21/461

(52) U.S. Cl. 438/710; 438/725; 438/745

(57) ABSTRACT

A method for removing polymer from a wafer is provided. The wafer has an opening already formed thereon and a patterned photoresist layer on the wafer for forming the opening has already been removed before performing the method. The method includes performing a plasma cleaning process to remove the polymer on the surface of the wafer. The plasma-producing gases include hydrogen-containing gases.

### BACKGROUND OF THE INVENTION

1. Field of the Invention

The present invention relates to a semiconductor fabrication process. More particularly, the present invention relates to a method for removing polymer from a wafer and a method for removing polymer in an interconnect process.

2. Description of the Related Art

An integrated circuit device normally consists of indefinite films with different thicknesses after a number of photolithographic and etching processes. No matter in a deposition process of forming films or in a photolithographic and etching process, some of the reacted products will ultimately be deposited on the wafer and on the inner surface of the reaction chamber, and those to be etched in the etching process might dropped on it, too. Furthermore, beside the target products, a processing reaction may also produce some byproducts. These byproducts or the reacted products on the inner surface of the reaction chamber may be shaken off and drop on the surface of the wafer to become a source of larger micro-particles when the device is further processed or transported from one place to another. The defects resulting from these larger micro-particles not only will affect the yield of the devices, but also lead to a drop in the product quality.

In the fabrication of copper interconnect, for example, a lot of larger polymer-like residues are left behind on the surface of a wafer after the etching stop layer above the copper line is removed to form an opening that exposes the copper line. Because the line width of each interconnect is typically very narrow, these polymer-like residues may block the entire opening or lodge inside the opening. Besides, there may be produced some smaller polymer residues in the opening during the process.

Therefore, if these larger polymer-like residues on the surface of the wafer and these smaller polymer residues in the opening are not removed before a subsequent copper deposition process, the copper material can not be deposited in the opening completely that voids are formed in the copper layers. After a subsequent chemical-mechanical polishing operation, copper missing problem will emerge. The problem of copper missing does not only lead to a drop in the processing yield, but also results in a decrease of the electrical performance of the device.

In general, the smaller polymer residues are often washed by a wet etching process in the conventional method, but those larger polymer-like residues on the surface of the wafer are not dealt with. Accordingly, it is desired to provide a method which can not only remove the polymer in the openings but also clean the polymer on the surface of the wafer.

### SUMMARY OF THE INVENTION

Accordingly, at least one objective of the present invention is to provide a method for removing polymer on a wafer and a method for removing polymer in an interconnect process so that the processing yield and the quality of the products can be improved.

At least another objective of the present invention is to provide a method for removing polymer on a wafer and a method for removing polymer in an interconnect process that the problem of forming an incompletely deposited conductive layer can be avoided.

To achieve these and other advantages and in accordance with the purpose of the invention, as embodied and broadly described herein, the invention provides a method for removing polymer on a wafer. An opening is formed on the wafer and a patterned photoresist layer on the wafer for forming the opening has already been removed before performing the method. The method includes performing a plasma cleaning process to remove the polymer on the surface of the wafer. The plasma-producing gases include hydrogen-containing gases.

In the aforementioned method of removing polymer from the wafer in one embodiment of the present invention, the method of forming the opening includes the following steps. First, a substrate is provided. The substrate has an etching stop layer and an inter metal dielectric layer already formed thereon. Then, a patterned photoresist layer is formed over the inter metal dielectric layer. Using the patterned photoresist layer as a mask, a portion of the inter metal dielectric layer is removed to expose a portion of the etching stop layer. After that, the patterned photoresist layer and the exposed etching stop layer are removed to form the opening.

In the aforementioned method of removing polymer from the wafer in one embodiment of the present invention, the hydrogen-containing gases comprise hydrogen or ammonia.

In the aforementioned method of removing polymer from the wafer in one embodiment of the present invention, the plasma-producing gases further include nitrogen, helium or argon.

In the aforementioned method of removing polymer from the wafer in one embodiment of the present invention, after performing the plasma cleaning process further includes performing a wet cleaning process to remove the polymer in the opening on the wafer.

In the aforementioned method of removing polymer from the wafer in one embodiment of the present invention, the wafer further includes a conductive portion and the opening exposes the conductive portion. The material of the conductive portion includes, for example, copper.

In the aforementioned method of removing polymer from the wafer in one embodiment of the present invention, the plasma cleaning process is performed at a temperature between about 30° C.˜400° C. for a time period between about 10 seconds to 60 minutes.

In the aforementioned method of removing polymer from the wafer in one embodiment of the present invention, the opening includes a trench, a via hole, a contact hole or a dual damascene opening.

In the aforementioned method of removing polymer from the wafer in one embodiment of the present invention, the plasma cleaning process is performed at a power rating between 100W˜2500W. Furthermore, the ratio between the hydrogen-containing gas and (all) the plasma-producing gases is between 0.5%˜30%, for example.

The present invention also provides a method for removing polymer in an interconnect process. The method includes the following steps. First, a substrate is provided. The substrate has a conductive portion already formed therein. Furthermore, the substrate has an etching stop layer and an inter metal dielectric layer already formed thereon. Then, a patterned photoresist layer is formed over the inter metal dielectric layer. Using the patterned photoresist layer as a mask, a portion of the inter metal dielectric layer is removed to expose a portion of the etching stop layer. Next, the patterned photoresist layer is removed and then the exposed etching stop layer is removed to form an opening that exposes the conductive portion. After that, a plasma cleaning process is performed to remove the polymer on the surface of the inter metal dielectric layer. The plasma-producing gases in the plasma cleaning process include a hydrogen-containing gas. Finally, a conductive layer is formed over the substrate.

In the aforementioned method of removing polymer in the interconnect process according to one embodiment of the present invention, after performing the plasma cleaning process further includes performing a wet cleaning process to remove the polymer in the opening.

In the aforementioned method of removing polymer in the interconnect process according to one embodiment of the present invention, the hydrogen-containing gases comprise hydrogen or ammonia. The aforementioned plasma-producing gases further include nitrogen, helium or argon.

In the aforementioned method of removing polymer in the interconnect process according to one embodiment of the present invention, the plasma cleaning process is performed at a temperature between about 30° C.˜400° C. for a time period between about 10 seconds to 60 minutes.

In the aforementioned method of removing polymer in the interconnect process according to one embodiment of the present invention, the material of the aforementioned conductive portion includes, for example, copper.

In the aforementioned method of removing polymer in the interconnect process according to one embodiment of the present invention, the aforementioned opening includes a trench, a via hole, a contact hole or a dual damascene opening.

In the present invention, hydrogen-containing gases are used in a plasma cleaning process to remove polymer-like compounds on the surface of the wafer so that incomplete deposition will not occur in the subsequently formed film layers. Hence, the processing yield is increased and the quality of product is improved. In the interconnect process, hydrogen-containing gases are also used in a plasma cleaning process so that the conductive portion exposed through the opening will not be damaged by the plasma-producing gases. As a result, the thickness of the conductive portion (such as a conductive wire) is maintained so that interconnects can have a better electrical performance.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow diagram showing the steps for removing polymer from a wafer according to one embodiment of the present invention.

FIGS. 2A through 2C are schematic cross-sectional views showing the steps for removing polymer in an interconnect process according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

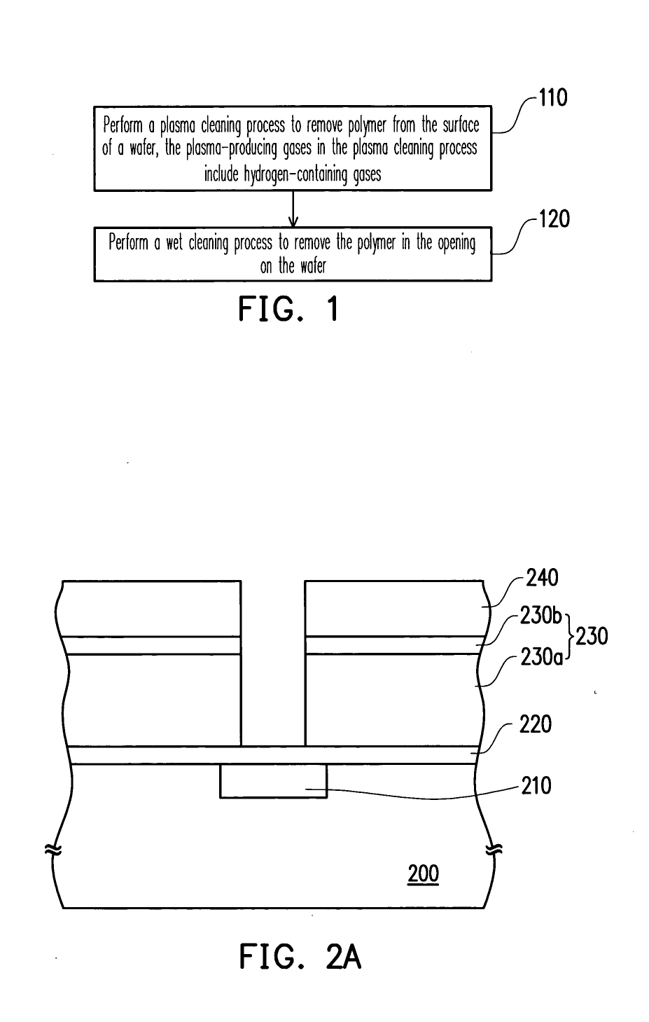

FIG. 1 is a flow diagram showing the steps for removing polymer from a wafer according to one embodiment of the present invention. As shown in FIG. 1, the method for removing polymer from a wafer according to the present invention is suitable for removing polymer from a wafer on which an opening has been formed. Wherein, a patterned photoresist layer used for forming the opening on the wafer has already been removed before performing the present method. The opening is a trench, a via hole, a contact hole or a dual damascene opening, for example. The present invention includes performing a plasma cleaning process after forming the opening but before depositing material in a subsequent process. The plasma cleaning process is to remove polymer from the surface of the wafer. The plasma-producing gases used in the plasma cleaning process include hydrogen-containing gases (step 110).

The hydrogen containing gases in the aforementioned plasma-producing gases are hydrogen or ammonia, for example. Beside the hydrogen-containing gases, the plasma-producing gases may include other gases such as nitrogen, helium or argon. The ratio of hydrogen-containing gases to (all) the plasma-producing gases is between about 0.5%˜30%, for example. The gas pressure of these gases is between 100 mTorr˜5 Torrs and the gas flow rate is between about 10˜10000 sccm, for example. The plasma cleaning process is performed at a temperature, for example, between about 30° C.˜400° C., but preferably greater than 100° C such as around 120° C. The plasma cleaning process is performed for between about 10 seconds to 60 minutes, but preferably about 2 minutes; and at a power rating of between about 100W˜2500W, for example.

After the plasma cleaning process, a wet cleaning process is performed to remove the polymer in the opening on the wafer (step 120). This is required because some residual polymer may still remain on the inner walls of the opening during the manufacturing process of the opening. The wet cleaning process is carried out for completely removing the residual polymers in the opening.

In the foregoing method of removing polymer on the wafer, the processing parameters of the plasma cleaning process are controlled to reduce polymer on the wafer (especially, the surface of the wafer). Hence, defects such as the incomplete deposition of the subsequently formed film layers on the wafer can be avoided. Ultimately, the production yield can be increased and the quality of the device can be improved.

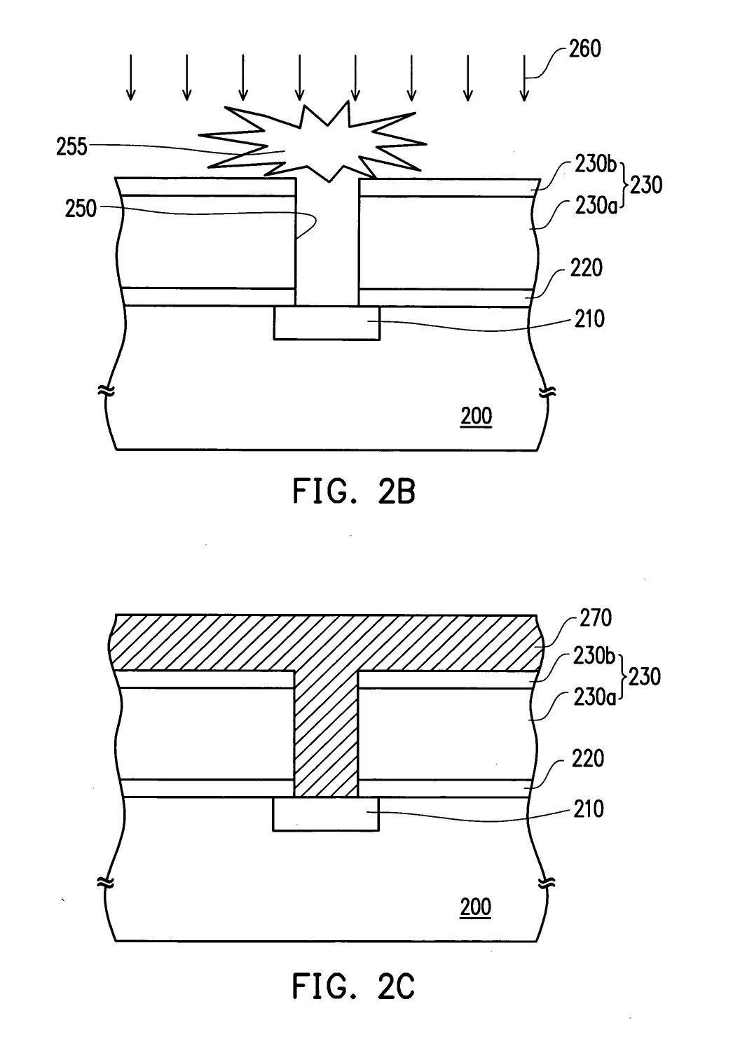

In the following, the method of removing polymer according to the present invention is applied to an interconnect process to serve as a particular example. FIGS. 2A through 2C are schematic cross-sectional views showing the steps for removing polymer in an interconnect process according to one embodiment of the present invention.

As shown in FIG. 2A, the present invention provides a method of removing polymer in an interconnect process. First, a substrate 200 is provided. The substrate 200 has a conductive portion 210 already formed therein. Furthermore, an etching stop layer 220 and an inter metal dielectric layer 230 have been already formed on the surface of the substrate 200. The substrate 200 has at least a device, for example. The device can be a metal-oxide-semiconductor (MOS) transistor such as an NMOS, a PMOS or a CMOS or a logic device such as an ROM, DRAM or SRAM. The conductive portion 210 is the source, drain or gate of the aforementioned device or a conductive wire, for example. The material of the etching stop layer 220 is silicon nitride, silicon carbide or silicon-carbon oxide, for example. The inter metal dielectric layer 230 comprises a low-k dielectric material layer 230a below and a cap layer 230b above, for example. The material of the low-k dielectric material layer 230a is potassium fluoride, fluorinated amorphous carbon, carbon-doped oxide, Parylene AF4, PAE or Cyclotene, for example.

Then, a patterned photoresist layer 240 is formed over the inter metal dielectric layer 230. The method of forming the patterned photoresist layer 240 includes depositing a layer of positive photoresist over the inter metal dielectric layer 230 in a spin-coating process, and performing a photo-exposure and development process thereafter. After that, using the patterned photoresist layer 240 as a mask, a portion of the inter metal dielectric layer 230 is removed to expose a portion of the etching stop layer 220. The method of removing a portion of the inter metal dielectric layer 230 includes performing a dry etching operation such as a reactive ion etching operation, for example.

As shown in FIG. 2B, the patterned photoresist layer 240 is removed. The method of removing the patterned photoresist layer 240 includes performing a oxygen plasma ashing process or a wet photoresist removing process, for example. Then, the exposed etching stop layer 220 is removed to form an opening 250 that exposes the conductive portion 210. If the conductive portion 210 is a source, a drain or a gate, then the opening 250 is a contact hole. If the conductive portion 210 is a wire, then the opening 250 is a via hole. Obviously, the opening 250 can be a trench or a dual damascene opening. In one embodiment, the conductive portion 210 is a wire fabricated using a material including copper, copper-aluminum alloy or copper-aluminum-silicon alloy, for example.

Next, as shown in FIG. 2B, an inspection is normally carried out after forming the opening 250. In the inspection, residue such as polymer compound 255 is often found on the surface of the wafer (the surface of the inter metal dielectric layer 230). Therefore, a plasma cleaning process 260 is performed to remove the polymer 255 on the surface of the wafer (the surface of the inter metal dielectric layer 230). The plasma-producing gases used in the plasma cleaning process 260 include hydrogen-containing gases.

The aforementioned hydrogen containing gases in the plasma-producing gases include hydrogen or ammonia, for example. Aside from the hydrogen-containing gases, the plasma-producing gases may include other gases including nitrogen, helium or argon, for example. The ratio of hydrogen-containing gases to (all) the plasma-producing gases is between about 0.5%˜30%, for example. The gas pressure of these gases is between 100 mTorr˜5 Torrs and the gas flow rate is between about 10˜10000 sccm, for example. The plasma cleaning process 260 is performed at a temperature between about 30° C.˜400° C. for a time period of about 10 seconds to 60 minutes. Preferably, the plasma cleaning process 260 is performed at a temperature greater than 100° C. such as 120° C. for about 2 minutes. Furthermore, the plasma cleaning process 260 is performed at a set power rating of between about 100W˜2500W, for example.

After the plasma cleaning process 260, a wet cleaning process, for example, is performed to remove the residual polymer in the opening 250 due to the manufacturing process of it. Thus, the wet cleaning process can be used for removing polymer on the inner wall of the opening 250 so that the subsequent process can be better controlled.

As shown in FIGS. 2B and 2C, the polymer 255 on the surface of the wafer (the surface of the inter metal dielectric layer 230) is removed after the plasma cleaning process 260 while the polymer on the inner wall of the opening 250 is removed after the wet cleaning process. Then, a conductive layer 270 is formed over the substrate 200 (over the inter metal dielectric layer 230 the conductive portion 210). The conductive layer 270 is fabricated using a conductive material selected from a group consisting of copper, copper-aluminum alloy, copper-aluminum-silicon alloy, tungsten, aluminum, platinum, gold and other alloy, for example. The method of forming the conductive layer 270 includes, for example, performing a chemical vapor deposition process or a physical vapor deposition process. Obviously, the conductive layer 270 can be patterned to form a plug or a linked plug with wire. Since subsequent processes for forming the interconnect should be familiar to those skilled in this technical field, a detailed description is omitted here.

In summary, the present invention provides a method of removing polymer by utilizing hydrogen-containing gases as plasma-producing gases in a plasma cleaning process. Thus, the copper-containing layer will not be oxidized or damaged so that the original conductive properties of the film layers can be maintained. Moreover, using hydrogen-containing gases as plasma-producing gases is a useful aid in the process of breaking down the internal bonds of the polymer because the hydrogen is such a small atom. Hence, the plasma cleaning process is effective in removing the polymer. As a result, there will be very little polymer on the surface of the wafer to cause problems such as incomplete deposition of the metallic layers or defects in the metallic layer. Ultimately, not only is the production yield increased, but also a higher quality product with better electrical conductivity is produced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for removing polymer from a wafer, wherein an opening is formed on the wafer and a patterned photoresist layer for forming the opening has been removed, the method comprising the step of:
performing a plasma cleaning process to remove polymer on the surface of the wafer, wherein a plasma-producing gas used in the plasma cleaning process includes a hydrogen gas and an inert gas.

2. The method of claim 1, wherein the steps for forming the opening include:
providing a substrate, and an etching stop layer and an inter metal dielectric layer are formed on the surface of the substrate;
forming a patterned photoresist layer over the inter metal dielectric layer;
removing a portion of the inter metal dielectric layer using the patterned photoresist layer as a mask to expose a portion of the etching stop layer;
removing the patterned photoresist layer; and
removing the exposed etching stop layer to form the opening.

3. (canceled)

4. The method of claim 1, wherein the inert gas includes helium or argon.

5. The method of claim 1, wherein after performing the plasma cleaning process, further includes performing a wet cleaning process to remove the polymer in the opening on the wafer.

6. The method of claim 1, wherein the wafer further includes a conductive portion exposed by the opening.

7. The method of claim 6, wherein the material constituting the conductive portion includes copper.

8. The method of claim 1, wherein the plasma cleaning process is performed at a temperature between about 30° C.˜400° C.

9. The method of claim 1, wherein the plasma cleaning process is performed for a time period between about 10 seconds to 60 minutes.

10. The method of claim 1, wherein the opening includes a trench, a via hole, a contact hole or a dual damascene opening.

11. The method of claim 1, wherein the plasma cleaning process is performed at a power rating of between 100W˜2500W.

12. The method of claim 1, wherein the ratio between the hydrogen-containing gas to the plasma-producing gas is between about 0.5%˜30%.

13. A method of removing polymer in an interconnect process, comprising the steps of:
providing a substrate, a conductive portion is formed in the substrate, and an etching stop layer and an inter metal dielectric layer are formed on the surface of the substrate;
forming a patterned photoresist layer over the inter metal dielectric layer;
removing a portion of the inter metal dielectric layer using the patterned photoresist layer as a mask to expose a portion of the etching stop layer;
removing the patterned photoresist layer;
removing the exposed etching stop layer to form an opening, wherein the opening exposes the conductive portion;
performing a plasma cleaning process to remove polymer from the surface of the inter metal dielectric layer, wherein a plasma-producing gas used in the plasma cleaning process includes hydrogen gas and an inert gas; and
forming a conductive layer over the substrate.

14. The method of claim 13, wherein after performing the plasma cleaning process, further includes performing a wet cleaning process to remove the polymer in the opening.

15. (canceled)

16. The method of claim 13, wherein the inert gas includes helium or argon.

17. The method of claim 13, wherein the plasma cleaning process is performed at a temperature between about 30° C.˜400° C.

18. The method of claim 13, wherein the plasma cleaning process is performed for a time period between about 10 seconds to 60 minutes.

19. The method of claim 13, wherein the material constituting the conductive portion includes copper.

20. The method of claim 13, wherein the opening includes a trench, a via hole, a contact hole or a dual damascene opening.
